(19) United States
(12) Patent Application Publication
(10) Pub. No.: US 2012/0315754 A1
(43) Pub. Date: Dec. 13, 2012

(54) INTERCONNECTION BARRIER MATERIAL DEVICE AND METHOD

(75) Inventors: Xiaoyun Zhu, Boise, ID (US); Dale W. Collins, Boise, ID (US); Joseph Lindgren, Boise, ID (US); Anurag Jindal, Boise, ID (US)

(73) Assignee: MICRON TECHNOLOGY, INC., BOISE, ID (US)

(21) Appl. No.: 13/155,908

(22) Filed: Jun. 8, 2011

(51) Int. Cl. H01L 21/768

(52) U.S. Cl. 438/653; 257/E21.584

(57) ABSTRACT

Interconnects containing ruthenium and methods of forming can include utilization of a sacrificial protective material. Planarization or other material removal operations can be performed on a substrate having a recess, the recess containing a ruthenium containing material along with the sacrificial protective material. The protective material is later removed, and a conductor can be filled in the remaining recess.

### TECHNICAL FIELD

Various embodiments described herein relate to apparatus, systems, and methods associated with interconnects, such as contacts and interconnection lines.

### BACKGROUND

Ruthenium has been investigated as a barrier and/or seed material. Using ruthenium in place of other barrier metals such as tantalum can lower contact resistance, improve adhesion of subsequent conductors, and improve gap filling capability due to its seed enhancement at small dimensions.

Ruthenium is a rare transition metal of the platinum group of the periodic table and chemically resistant to most other chemicals. Compared to ruthenium, copper is a more reactive metal. Copper is more easily corroded under either acidic and alkali conditions. When ruthenium is used as barrier for copper interconnects, processing operations such as slurry polishing and post chemical mechanical processing (CMP) chemistry clean accelerates copper chemical dissolution much faster than ruthenium, resulting in preferential material removal, such as dishing, voiding and corrosion of copper structures, while ruthenium is removed much slower.

It is desirable to improve processes using ruthenium in interconnects.

### BRIEF DESCRIPTION OF THE DRAWINGS

FIGS. 1-2 show a substrate in various stages of processing according to an embodiment of the invention.

FIG. 3A shows a substrate in a stage of processing with a protective material according to an embodiment of the invention.

FIG. 3B shows another substrate in a stage of processing with a protective material according to an embodiment of the invention.

FIGS. 4-7 show a substrate in various stages of processing according to an embodiment of the invention.

FIG. 8 shows an information handling system utilizing interconnects formed according to embodiments of the invention.

### DETAILED DESCRIPTION

In the following detailed description of the invention, reference is made to the accompanying drawings that form a part hereof and in which are shown, by way of illustration, specific embodiments in which the invention may be practiced. These embodiments are described in sufficient detail to enable those skilled in the art to practice the invention. Other embodiments may be utilized and structural, logical, and electrical changes may be made.

The term “horizontal” as used in this application is defined as a plane parallel to the conventional plane or surface of a substrate, such as a wafer or die, regardless of the orientation of the substrate. The term “vertical” refers to a direction perpendicular to the horizontal as defined above. Prepositions, such as “on”, “side” (as in “sidewall”), “higher”, “lower”, “over” and “under” are defined with respect to the conventional plane or surface being on the top surface of the substrate, regardless of the orientation of the substrate. The following detailed description is, therefore, not to be taken in a limiting sense, and the scope of the present invention is defined only by the appended claims, along with the full scope of equivalents to which such claims are entitled.

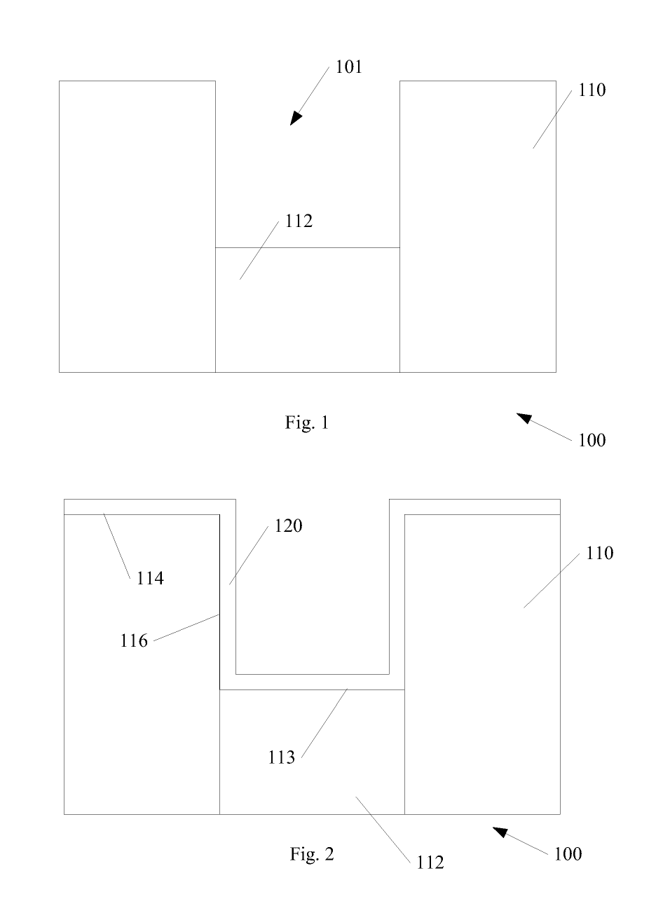

FIG. 1 shows a substrate 100, including an interconnect, such as an electrical contact 112, and an electrical isolation region 110. The electrical contact 112 is located within a recess 101 of the isolation region 110. In one example, the recess is part of a contact (e.g. a via) in a semiconductor device used to electrically connect an electronic device such as a transistor, capacitor, memory cell, etc. with other components. In one example the recess 101 includes an elongated recess (e.g. trench) used to form an interconnect such as an interconnection line in an electronic device.

Examples of electrical contacts 112 can include tungsten or tungsten alloy contacts. Although the contact 112 of FIG. 1 is shown as a single block, in one example, the electrical contact 112 can include layers of material. In selected examples, the isolation region 110 includes a dielectric material, such as silicon oxide, silicon nitride, or other electrically insulating materials.

FIG. 2 shows a material 120 containing ruthenium formed (e.g., deposited) over the electrical contact 112 in the recess 101. In one example the material 120 serves as an adhesion layer and/or a barrier layer to prevent or reduce diffusion or migration of materials above and/or below the material 120. In one example, the material 120 containing ruthenium comprises, consists, or consists essentially of substantially pure ruthenium metal. In other examples, the material 120 comprises, consists, or consists essentially of a ruthenium alloy of two or more components. In other examples, the material 120 containing ruthenium includes two or more conductive layers. One layered example comprises, consists, or consists essentially of a ruthenium containing layer and a titanium nitride layer. Another layered example comprises, consists, or consists essentially of a ruthenium containing layer and a tantalum nitride layer. Another layered example comprises, consists, or consists essentially of a ruthenium containing layer and a tantalum layer. In selected layer examples, the ruthenium containing layer comprises, consists, or consists essentially of ruthenium metal or a ruthenium alloy.

FIG. 2 shows the material 120 containing ruthenium deposited as a conformal layer, covering at least a portion of a top surface 114 and sidewalls 116 of the isolation region 110, and a top surface 113 of the electrical contact 112. Although a thickness of the material 120 is shown as substantially uniform, other examples may include anisotropic deposition. In one example, the thickness of the coating 120 is between 100 and 130 angstroms.

In one example, the material 120 containing ruthenium is deposited using chemical vapor deposition. Other deposition methods include, but are not limited to, atomic layer deposition (ALD) and physical vapor deposition.

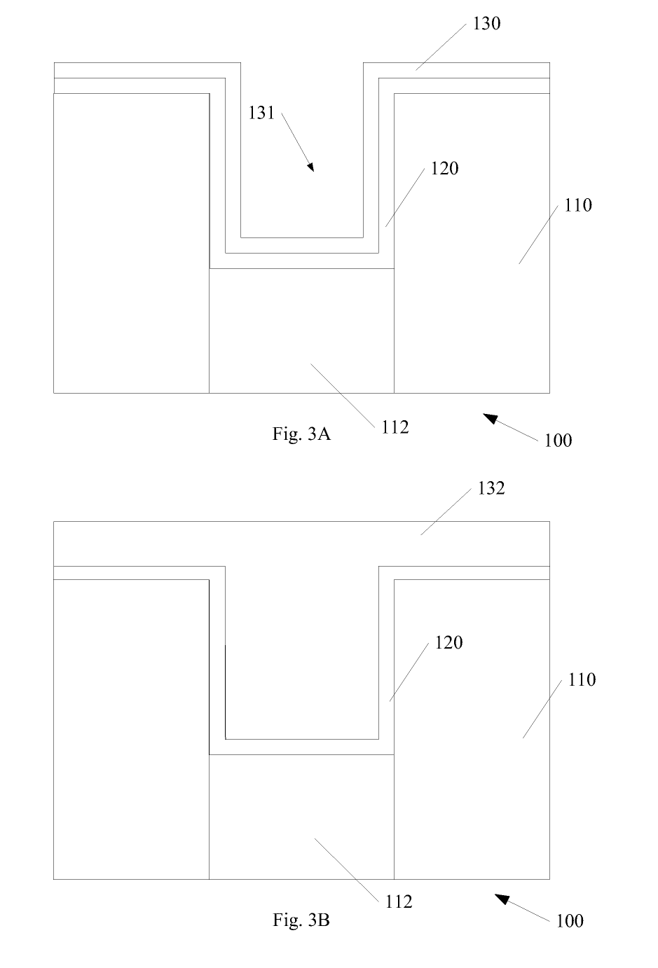

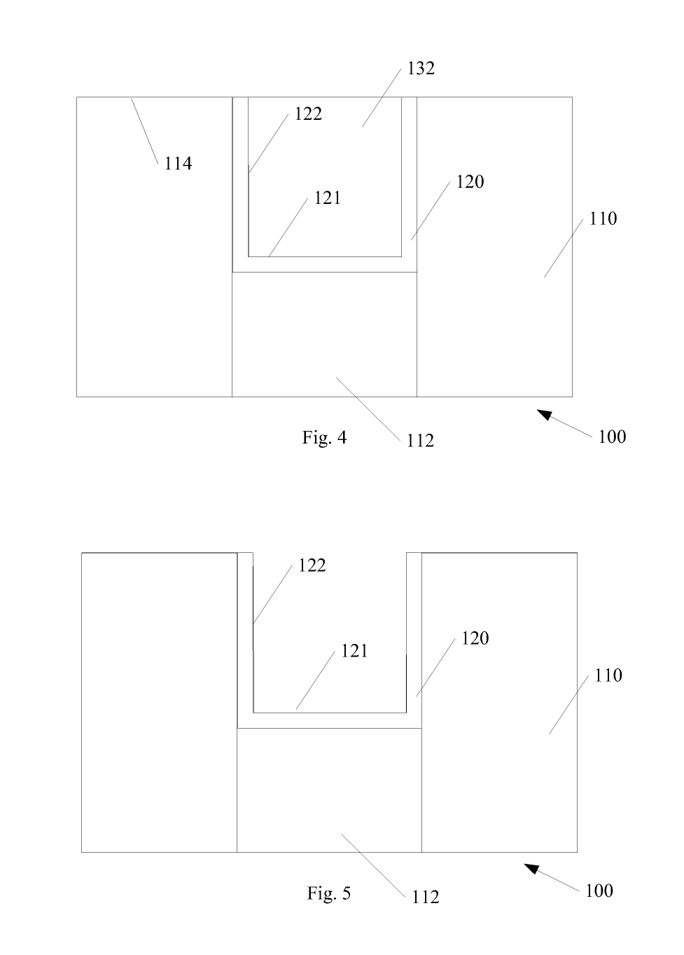

FIGS. 3A and 3B show examples of a protective material formed over the material 120 containing ruthenium. In FIG. 3A, a conformal coating of protective material 130 is shown covering the material 120 at a substantially uniform thickness. The example configuration of FIG. 3A leaves a gap 131 within the recess 101. FIG. 3B shows another configuration of a protective material 132 formed over the material 120 containing ruthenium. In FIG. 3B, a protective material 132 is shown filling in the gap in the recess 101 over the ruthenium containing material 120.

The protective material 130, 132 provides chemical and mechanical protection of the material 120 containing ruthenium. The protective material chosen is substantially non-reactive with the material 120 containing ruthenium, and is easily removed at a later stage of processing using methods such as etching, washing, buffing, etc.

One example of a suitable protective material includes silicon nitride (Si₃N₄). Another example of a suitable protective material includes resist carbon. Other materials with selective reactivity or selective removability with respect to ruthenium can be used in various embodiments.

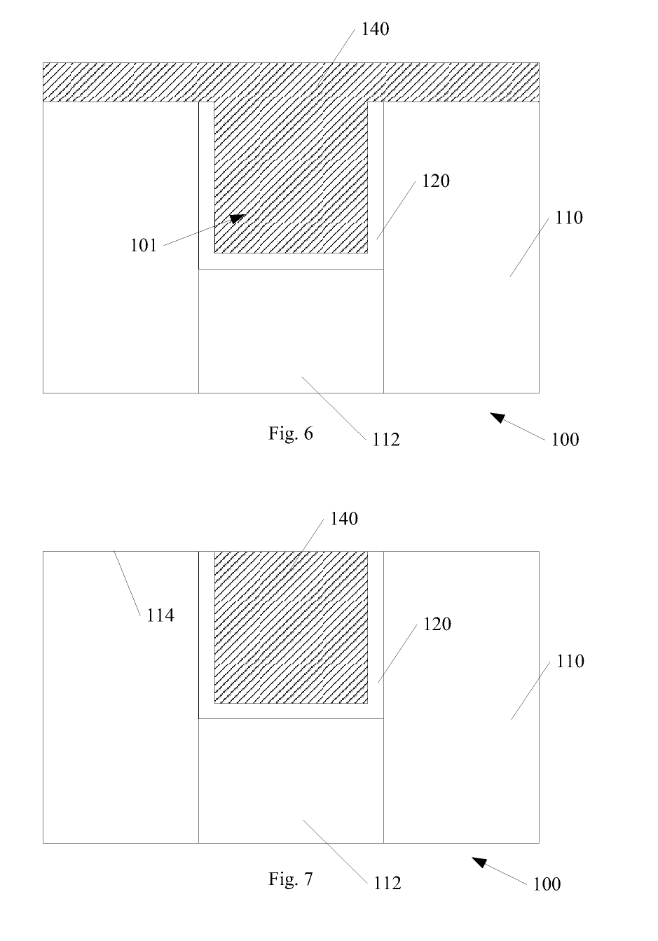

FIG. 4 illustrates removal of an upper portion of the material 120 containing ruthenium and the example protective material 132 (as well as a portion of the isolation region 110). The example protective material 132 is used for illustration, however processing operations in the following description can also be used with embodiments of protective material 130 from FIG. 3A.

In one example, the removal includes a planarization operation of the top surface 114 of the substrate 100. In one example, the planarization includes a chemical-mechanical polishing (CMP) operation. The slurry in a CMP operation can be selected to be particularly aggressive when removing ruthenium, due to ruthenium's relatively inert properties to chemical removal, and due to ruthenium's mechanical hardness and strength. In the examples shown, the protective material 132 is a sacrificial material that protects a bottom 121 and sides 122 of the material 120 containing ruthenium during the harsh CMP process. Because the protective material 132 is sacrificial, damage to the protective material 132 during a CMP operation does not matter, provided the bottom 121 and sides 122 of the material 120 containing ruthenium remain protected. The CMP process on top surface 114 can shorten trenches with minimal oxide recess, thus potentially resulting in an easier aspect ratio to fill.

After removal of the upper portions of the material 120 and the protective material 132, the remainder of the protective material 132 is removed, as illustrated in FIG. 5. In one example, an etch operation is used to remove the remaining protective material 132. Examples of chemical solutions that remove the protective material 132 without removing the material 120 containing ruthenium include 85% H₃PO₄:15% H₂O; H₃PO₄ and H₂O₂ solutions; H₂O+H₂O₂+HCl solutions, or other suitable solutions that strip the protective material 132 without significant removal of the material 120 containing ruthenium. Other processes such as ultrasonic cleaning and/or washing, etc. may also be used. As described above, the remaining material 120 is in good shape, and the bottom 121 and sides 122 of the material 120 have been protected.

FIG. 6 shows a deposition of a conductor 140 into the recess 101, such as by PVD or electroplating. The material 120 containing ruthenium provides desirable properties such as wetting and/or adhesion ability. In one example the conductor is drawn into the recess 101, after heating to a flowable state, due to the chemical affinity between ruthenium and the conductor material chosen. In one example, the conductor 140 comprises, consists, or consists essentially of copper. In one example, the conductor 140 comprises, consists, or consists essentially of a copper alloy. Other examples of conductors may include aluminum, polysilicon, or other suitable conductive materials.

FIG. 7 shows another removal step, where an upper portion of the conductor 140 has been removed from the top surface 114 of the substrate 100. In one example the removal operation in FIG. 7 includes a CMP operation. The conductor 140 may be further processed, such as being subjected to a clean.

Because the relatively non-reactive and mechanically strong material 120 containing ruthenium has already been removed from the top surface 114, the subsequent removal of the upper portion of the conductor 140 is relatively straight forward. Differences in removal rate and reactivity between the conductor 140 and the material 120 containing ruthenium are mitigated by removing the respective materials in different operations. Integrity of the material 120 containing ruthenium is preserved during the removal process by the use of the sacrificial protective material.

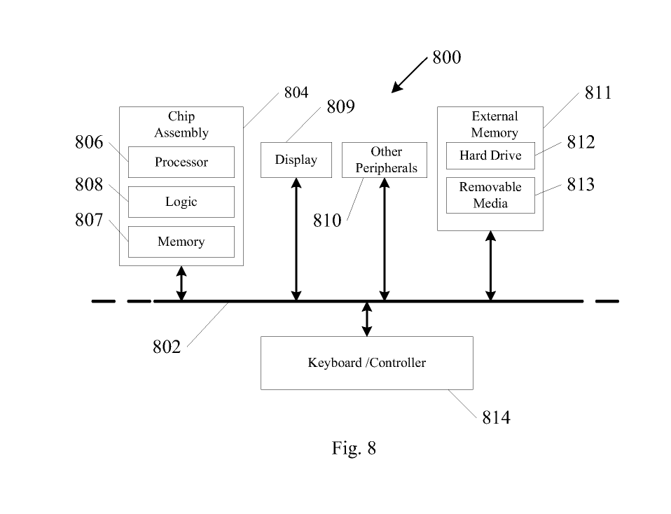

An embodiment of an information handling system such as a computer is included in FIG. 8 to show an embodiment of a high-level device application. FIG. 8 is a block diagram of an information handling system 800 incorporating a substrate such as a chip or chip assembly 804 that includes an interconnect such as a contact or interconnection line formed according to an embodiment of the invention. For example, the memory device 807 or other chips may include ruthenium containing structures formed according to embodiments of the invention described above. The information handling system 800 shown in FIG. 8 is merely one example of a system in which the present invention can be used. Other examples include, but are not limited to, personal data assistants (PDAs), cellular telephones, MP3 players, aircraft, satellites, military vehicles, etc.

In this example, information handling system 800 comprises a data processing system that includes a system bus 802 to couple the various components of the system. System bus 802 provides communications links among the various components of the information handling system 800 and may be implemented as a single bus, as a combination of busses, or in any other suitable manner.

Chip assembly 804 is coupled to the system bus 802. Chip assembly 804 may include any circuit or operably compatible combination of circuits. In one embodiment, chip assembly 804 includes a processor 806 that can be of any type. As used herein, “processor” means any type of computational circuit such as, but not limited to, a microprocessor, a microcontroller, a graphics processor, a digital signal processor (DSP), or any other type of processor or processing circuit or cores thereof. Multiple processors such as “multi-core” devices are also within the scope of the invention.

In one embodiment, a memory device 807, is included in the chip assembly 804. Those skilled in the art will recognize that a wide variety of memory device configurations may be used in the chip assembly 804. Acceptable types of memory chips include, but are not limited to, Dynamic Random Access Memory (DRAMs) such as SDRAMs, SLDRAMs, RDRAMs and other DRAMs. Memory chip 807 can also include non-volatile memory such as NAND memory or NOR memory.

In one embodiment, additional logic chips 808 other than processor chips are included in the chip assembly 804. An example of a logic chip 808 other than a processor includes an analog to digital converter. Other circuits on logic chips 808 such as custom circuits, an application-specific integrated circuit (ASIC), etc. are also included in one embodiment of the invention.

Information handling system 800 may also include an external memory 811, which can include one or more memory elements, such as one or more hard drives 812, and/or one or more drives that handle removable media 813 such as floppy diskettes, compact disks (CDs), digital video disks (DVDs), and the like.

Information handling system 800 may also include a display device 809 such as a monitor, additional peripheral components 810, such as speakers, etc. and a keyboard and/or controller 814, which can include a mouse, or any other device that permits a system user to input data into and receive data from the information handling system 800.

While a number of embodiments of the invention are described, the above lists are not intended to be exhaustive. Although specific embodiments have been illustrated and described herein, it will be appreciated by those of ordinary skill in the art that any arrangement that is calculated to achieve the same purpose may be substituted for the specific embodiment shown. This application is intended to cover any adaptations or variations of embodiments of the present invention. It is to be understood that the above description is intended to be illustrative and not restrictive. Combinations of the above embodiments, and other embodiments, will be apparent to those of skill in the art upon studying the above description.

1. A method, comprising:
forming a ruthenium containing material in a recess of an isolation region;
forming a protective material over the ruthenium containing material;
removing an upper portion of the ruthenium containing material from a top surface of the isolation region while the protective material covers the ruthenium containing material within the recess;
removing the protective material from the recess; and
forming a conductor in the recess, in direct contact with the ruthenium containing material.

2. The method of claim 1, wherein removing an upper portion of the ruthenium containing material and the protective material includes planarizing the upper portion of the ruthenium containing material and the protective material.

3. The method of claim 2, wherein planarizing includes chemical-mechanical polishing.

4. The method of claim 1, wherein the conductor includes copper.

5. The method of claim 1, wherein the ruthenium containing material comprises a ruthenium containing layer and a titanium nitride layer.

6. The method of claim 1, wherein the ruthenium containing material comprises ruthenium metal.

7. The method of claim 1, wherein the ruthenium containing material comprises a ruthenium containing layer and a tantalum layer.

8. The method of claim 1, wherein the ruthenium containing material comprises a ruthenium alloy.

9. The method of claim 1, wherein the ruthenium containing material comprises substantially pure ruthenium metal.

10. The method of claim 1, wherein forming a protective material over the ruthenium containing material includes depositing a silicon nitride layer.

11. The method of claim 1, wherein forming a protective material over the ruthenium containing material includes depositing a resist carbon layer.

12. The method of claim 1, wherein the recess includes an elongated trench.

13. The method of claim 1, wherein removing the protective material from the recess includes removal using an 85% H₃PO₄:15% H₂O solution.

14. The method of claim 1, wherein removing the protective material from the recess includes removal using an H₃PO₄ and H₂O₂ solution at 140 degrees C.

15. The method of claim 1, wherein removing the protective material from the recess includes removal using an H₂O+H₂O₂+HCl solution at 70 degrees C.

16. A method, comprising:
forming a ruthenium containing material in a recess;
forming a protective material over the ruthenium containing material;
removing an upper portion of the ruthenium containing material using chemical-mechanical polishing while the protective material covers the ruthenium containing material within the recess;
selectively etching the protective material to remove the protective material from the recess; and
forming a copper containing material in the recess, in direct contact with the ruthenium containing material.

17. The method of claim 16, wherein forming a protective material over the ruthenium containing material includes depositing a silicon nitride layer.

18. The method of claim 16, wherein forming a protective material over the ruthenium containing material includes depositing a resist carbon layer.

19. The method of claim 16, wherein the ruthenium containing material comprises titanium nitride.

20. The method of claim 16, wherein the ruthenium containing material comprises tantalum.

21. The method of claim 16, wherein the ruthenium containing material comprises tantalum nitride.

22. A method, comprising:
forming a contact within a recess;
forming a material containing ruthenium over the contact in the recess;
forming a protective material over the material containing ruthenium;
planarizing the material containing ruthenium and the protective material while the protective material covers the material containing ruthenium within the recess;
removing the protective material from the recess; and
forming a conductor in the recess, in direct contact with the material containing ruthenium.

23. The method of claim 22, wherein the conductor comprises copper.

24. The method of claim 22, wherein the conductor comprises aluminum.

25. The method of claim 22, wherein the conductor comprises polysilicon.

26. The method of claim 22, wherein the material containing ruthenium comprises substantially pure ruthenium metal.

27. The method of claim 22, wherein the material containing ruthenium comprises an alloy including ruthenium.
